(19) United States
(12) Patent Application Publication
(10) Pub. No.: US 2017/0012150 A1
(43) Pub. Date: Jan. 12, 2017

(54) SUBSTRATE AND ELECTRONIC DEVICE

(71) Applicant: FUJITSU LIMITED, Kawasaki-shi (JP)

(72) Inventor: Shunji Baba, Yokohama (JP)

(73) Assignee: FUJITSU LIMITED, Kawasaki-shi (JP)

(21) Appl. No.: 15/168,302

(22) Filed: May 31, 2016

(30) Foreign Application Priority Data
Jul. 9, 2015 (JP) 2015-137628

(51) Int. Cl. H01L 31/048; H01L 31/0475; H01L 31/02

(52) U.S. Cl. CPC H01L 31/048; H01L 31/02021; H01L 31/0475

(57) ABSTRACT

A substrate includes: a base member that has flexibility and insulation properties; an electrically conductive member that is disposed on a top surface of the base member and that has flexibility and electrical conductivity; an electronic component that is disposed over the base member and that includes a terminal joined to the electrically conductive member; and a reinforcing member that is disposed on a bottom surface of the base member at a portion corresponding to a portion of the top surface of the base member at which the electrically conductive member is disposed, wherein the reinforcing member is larger in size than an area over which the terminal and the electrically conductive member are joined together.

### CROSS-REFERENCE TO RELATED APPLICATION

This application is based upon and claims the benefit of priority of the prior Japanese Patent Application No. 2015-137628, filed on Jul. 9, 2015, the entire contents of which are incorporated herein by reference.

### FIELD

The embodiments discussed herein are related to a substrate and an electronic device.

### BACKGROUND

There is an example of a base member made of an elastomer including a wiring board on which a wire containing an elastomer and a metal filler is disposed.

There is an example of an car-mounted packaging structure of an electronic device include a structure in which an electronic device is mounted on a polyimide layer of a flexible substrate having a two-layer structure including a polyimide layer and a reinforcing plate and in which a lead wire of the electronic device is electrically and physically joined to a pad mounted on the polyimide layer using a solder portion. In this structure, the reinforcing plate has a slit so as not to hinder thermal expansion or contraction of the flexible substrate while the wiring pattern is left unremoved, whereby the thermal stress that occurs is reduced.

There is an example of an electronic component include an electronic component in which an electronic component element is packaged in such a manner that multiple pairs of connection electrodes are formed on the surface of a flexible substrate made of a flexible resin and a reinforcing member is disposed on the surface of the flexible substrate or inside the flexible substrate.

There is an example of a double-sided flexible wiring board include a double-sided flexible wiring board having an area including a component mount land on one side and a conductor circuit on the opposite side.

In the packaging structure in which onboard components are mounted on a flexible base member, when the base member is deformed, a stress is more likely to concentrate on a junction portion between the terminal of each onboard component and an electrically conductive member on the base member. If, for example, a reinforcing member that covers the entire area of the onboard components is disposed on the base member to lessen the stress concentration, the reinforcing member may render deformation of the base member difficult.

The followings are reference documents.

### [Document 1] Japanese Laid-open Patent Publication No. 2012-33674,

### [Document 2] Japanese Laid-open Patent Publication No. 2002-198631,

### [Document 3] Japanese Laid-open Patent Publication No. 2013-84748 and

### [Document 4] Japanese Laid-open Patent Publication No. 2004-273609.

### SUMMARY

According to an aspect of the invention, a substrate includes: a base member that has flexibility and insulation properties; an electrically conductive member that is disposed on a top surface of the base member and that has flexibility and electrical conductivity; an electronic component that is disposed on the base member and that includes a terminal joined to the electrically conductive member; and a reinforcing member that is disposed on a bottom surface of the base member at a portion corresponding to a portion of the top surface of the base member at which the electrically conductive member is disposed, wherein the reinforcing member is larger in size than an area over which the terminal and the electrically conductive member are joined together.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a perspective view of a substrate according to a first embodiment in an unfolded state;

FIG. 2 is a perspective view of an electronic device according to the first embodiment;

FIG. 3 is a perspective view of the electronic device according to the first embodiment;

FIG. 4 is a plan view of the substrate (electronic device) according to the first embodiment in which a portion around a controlling unit is illustrated in an enlarged manner;

FIG. 5 is a front view of the substrate (electronic device) according to the first embodiment in which a portion around the controlling unit is illustrated in an enlarged manner and in the state where the base member is not deformed;

FIG. 6 is a front view of the substrate (electronic device) according to the first embodiment in which a portion around the controlling unit is illustrated in an enlarged manner and the base member is deformed;

FIG. 7 is a plan view of a substrate (electronic device) according to a second comparative example in which a portion around a controlling unit is illustrated in an enlarged manner;

FIG. 8 is a front view of the substrate (electronic device) according to the second comparative example in which a portion around the controlling unit is illustrated in an enlarged manner and in the state where the base member is deformed;

FIG. 9 is a plan view of a substrate (electronic device) according to a second embodiment in which a portion around a controlling unit is illustrated in an enlarged manner;

FIG. 10 is a plan view of a substrate (electronic device) according to a third embodiment in which a portion around a controlling unit is illustrated in an enlarged manner;

FIG. 11 is a perspective view of a substrate according to a fourth embodiment in an unfolded state;

FIG. 12 is a perspective view of an electronic device according to the fourth embodiment;

FIG. 13 is a perspective view of the electronic device according to the fourth embodiment;

FIG. 14 is a front view of the substrate (electronic device) according to the fourth embodiment in which a portion around a solar cell is illustrated in an enlarged manner; and

FIG. 15 is a front view of a substrate (electronic device) according to a third comparative example in which a portion around a solar cell is illustrated in an enlarged manner.

### DESCRIPTION OF EMBODIMENTS

Referring now to the drawings, a first embodiment is described in detail.

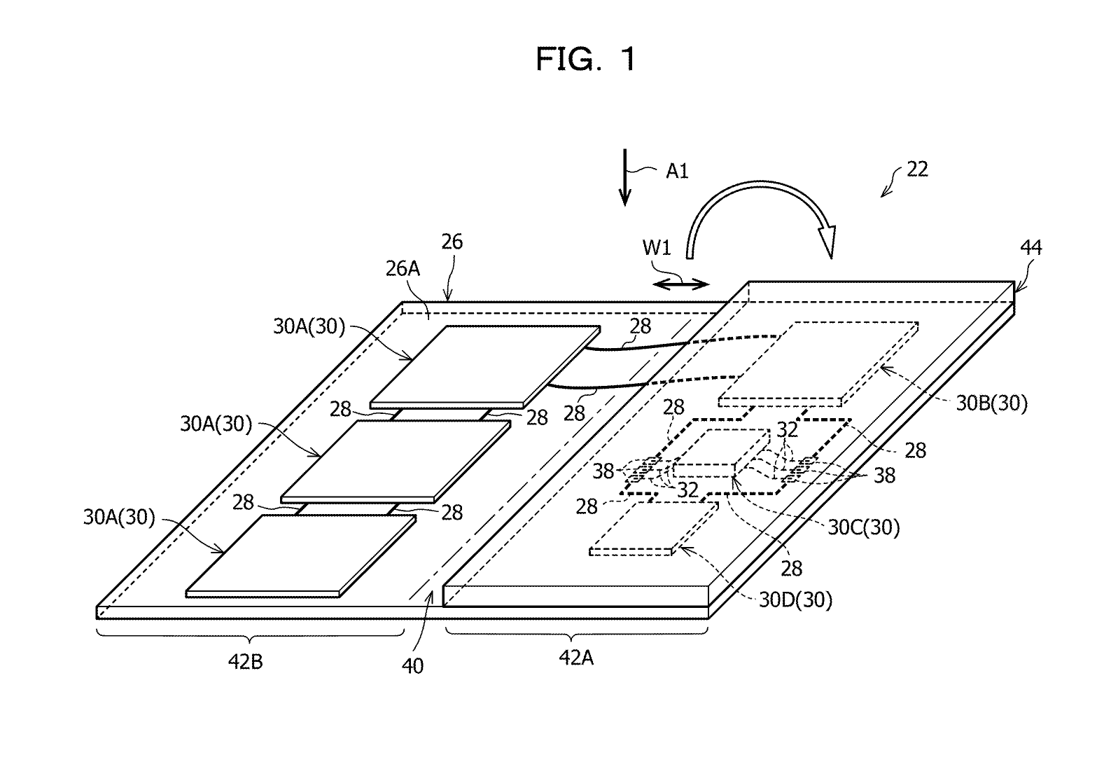

As illustrated in FIG. 1 to FIG. 3, a substrate 22 according to a first embodiment includes a plate-shaped base member 26. The base member 26 is made of a material having flexibility and insulation properties. A specific example of a material of the base member 26 is silicone but the material is not limited to silicone. In this embodiment, the base member 26 is rectangular when viewed in a plan (when viewed in a direction of arrow A1 in FIG. 1).

A first surface (upper surface in FIG. 1) of the base member 26 is a component onboard surface 26A. Conduction patterns 28 are formed on the component onboard surface 26A. The conduction patterns 28 are examples of an electrically conductive member. The conduction patterns 28 are made of a material having flexibility and electrical conductivity. Specific examples of such a material include an electrically conductive material obtained by dispersing electrically conductive metal particles in rubber. The rubber in the electrically conductive material functions as a binder, and thus the conduction patterns 28 have elasticity (flexibility). The volume of the electrically conductive material is preserved before and after the electrically conductive material is deformed. Thus, when, for example, the electrically conductive material expands in a specific direction, the electrically conductive material contracts in a direction perpendicular to the direction in which the electrically conductive material expands. When the electrically conductive material contracts in the direction perpendicular to the direction in which the electrically conductive material expands, the electrical conductivity metal particles come close to one another in the direction in which electrically conductive material contracts, whereby the electrically conductive material may retain its electrical conductivity.

Multiple electronic components 30 are mounted on the base member 26. FIG. 1 illustrates power supply units 30A, an electricity storage unit 30B, a controlling unit 30C, and a communication unit 30D as examples of the electronic components 30. For example, power of the power supply units 30A is accumulated in the electricity storage unit 30B and the controlling unit 30C is driven by being supplied with the power from the electricity storage unit 30B. The communication unit 30D transmits and receives signals from external devices. Besides these examples, other examples of the electronic components 30 include a sensor that detects physical properties such as the position of an electronic device 24 or the circumstances of the electronic device 24. The electronic components 30 are examples of onboard components.

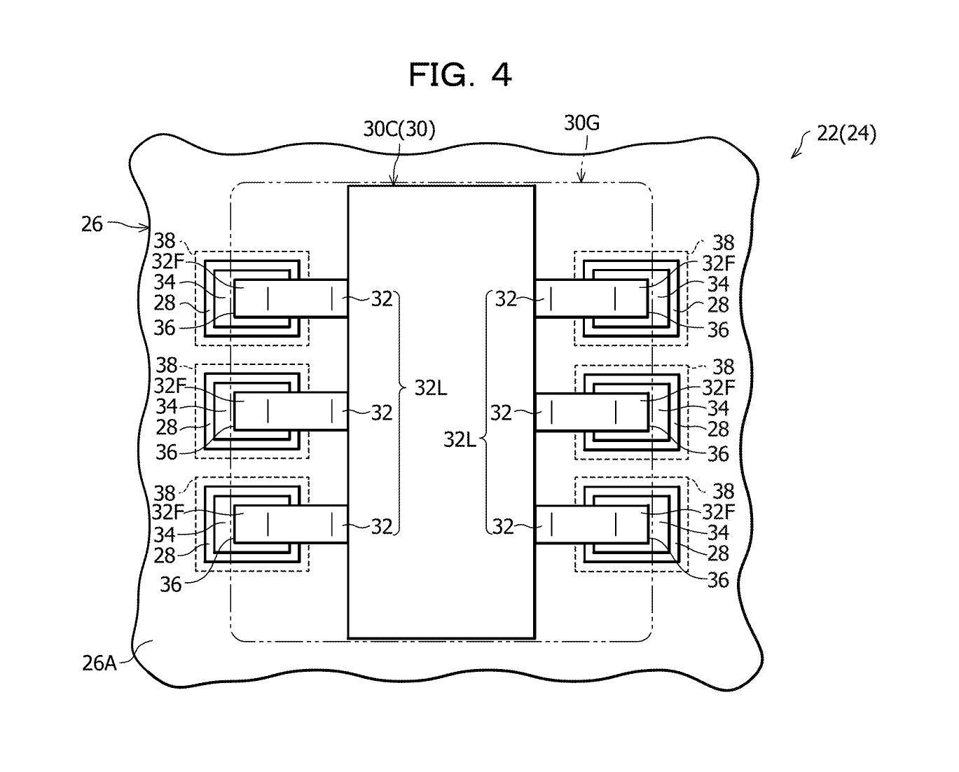

As illustrated in FIG. 4, in this embodiment, the controlling unit 30C includes multiple terminals 32 (six terminals in the example of FIG. 4). When the controlling unit 30C is viewed in a plan, the terminals 32 form multiple terminal rows 32L. In this embodiment, two terminal rows 32L are arranged so as to be parallel to each other and each terminal row 32L includes three terminals 32. The electronic components 30 other than the controlling unit 30C may have similar configurations in which terminals 32 are included and, as described below, a junction portion 36 between each terminal 32 and the corresponding conduction pattern 28 are reinforced with a reinforcing member disposed on a reinforcement surface 26B.

In this embodiment, the terminals 32 correspond one-to-one to the conduction patterns 28. An end portion of each terminal 32 is an opposing portion 32F that is parallel to the corresponding conduction pattern 28 when mounted on the base member 26. Each opposing portion 32F is joined to the corresponding conduction pattern 28 with a bonding agent 34 interposed between the opposing portion 32F and the conduction pattern 28 while opposing the conduction pattern 28. Thus, the controlling unit 30C is mounted on the base member 26 while being electrically connected to the base member 26. In this embodiment, an electrically conductive bonding agent is used as the bonding agent 34. Thus, the bonding agent 34 interposed between the opposing portion 32F and the conduction pattern 28 allows the terminal 32 and the conduction pattern 28 to conduct electricity between each other through the bonding agent 34. The portion at which the opposing portion 32F and the conduction pattern 28 oppose each other is referred to as the junction portion 36.

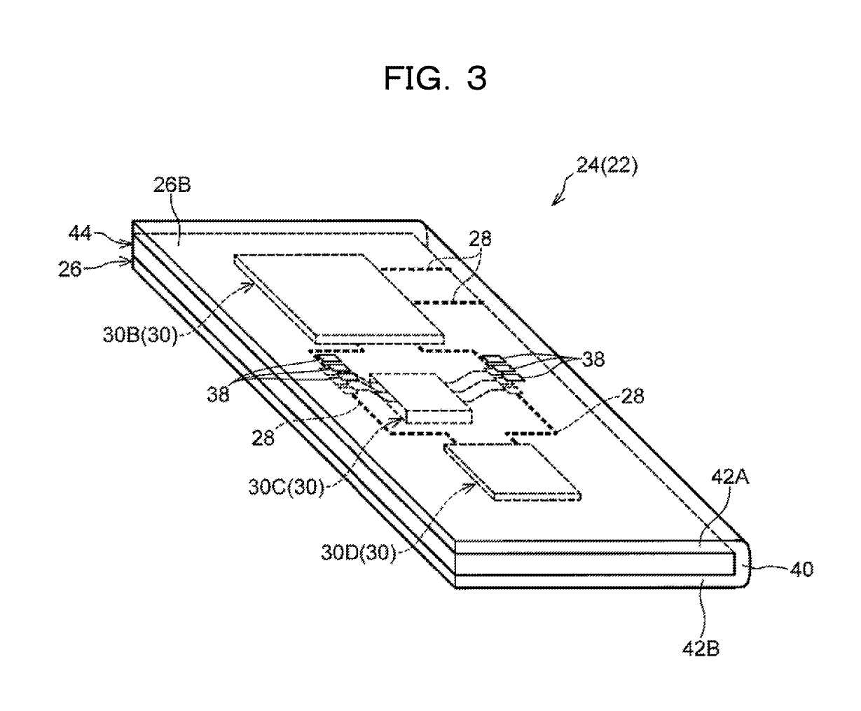

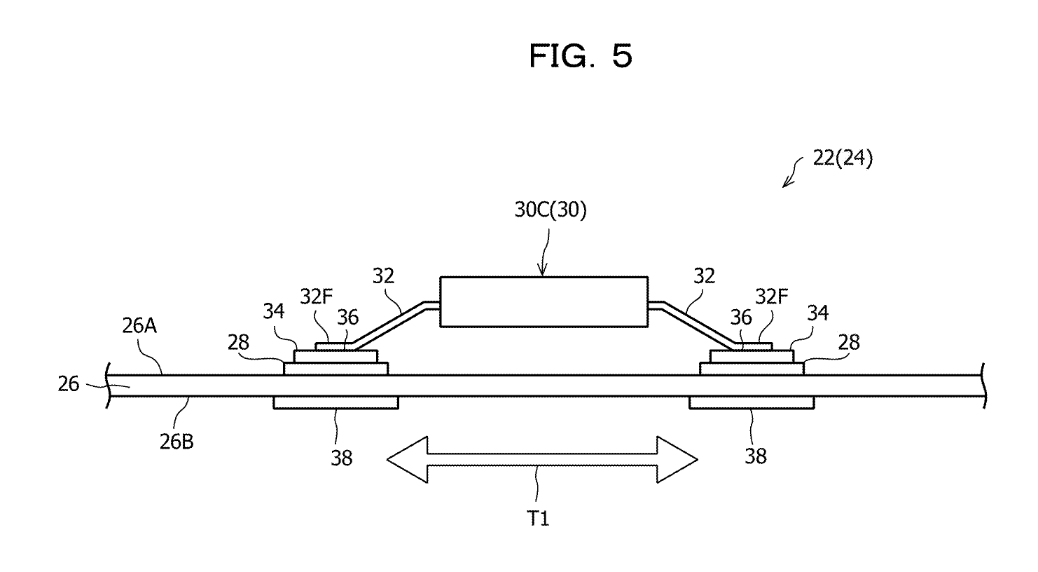

As illustrated in FIG. 3, FIG. 4, and FIG. 5, reinforcing members 38 are disposed on the reinforcement surface 26B of the base member 26, opposite to the component onboard surface 26A.

As illustrated in FIG. 4, in the first embodiment, the reinforcing members 38 are disposed so as to correspond to the conduction patterns 28 (terminals 32) when the base member 26 is viewed in a plan. In other words, the conduction patterns 28 (terminals 32) correspond one-to-one to the reinforcing members 38.

When the base member 26 is viewed in a plan, each reinforcing member 38 is larger than the corresponding opposing portion 32F (junction portion 32) on the corresponding conduction pattern 28. However, the reinforcing members 38 are smaller than the entire area 30G of the controlling unit 30C including the end portion of the terminal 32 when the base member 26 is viewed in a plan. Specifically, in a plan view, the reinforcing members 38 do not cover the entire area 30G of the controlling unit 30C.

The modulus of longitudinal elasticity of the reinforcing members 38 is higher than the modulus of longitudinal elasticity of the base member 26 and the modulus of longitudinal elasticity of the conduction patterns 28. Specifically, the reinforcing members 38 have a higher rigidity than the base member 26 and the conduction patterns 28 and thus are less likely to be deformed by external forces. The reinforcing members 38 thus reinforce the junction portions 36 from the side of the reinforcement surface 26B of the base member 26.

As illustrated in FIG. 1, the base member 26 has a fold portion 40 at a middle portion in the widthwise direction (direction of arrow W1). In this embodiment, the electricity storage unit 30B, the controlling unit 30C, and the communication unit 30D are disposed in a first area 42A (a right area in FIG. 1), defined by the fold portion 40, and the power supply units 30A are disposed in a second area 42B, defined by the fold portion 40.

A covering member 44 is disposed in the first area 42A. The covering member 44 is made of a material having insulation properties and flexibility. In a plan view, the covering member 44 is disposed so as to have such a shape as to cover the electricity storage unit 30B, the controlling unit 30C, and the communication unit 30D.

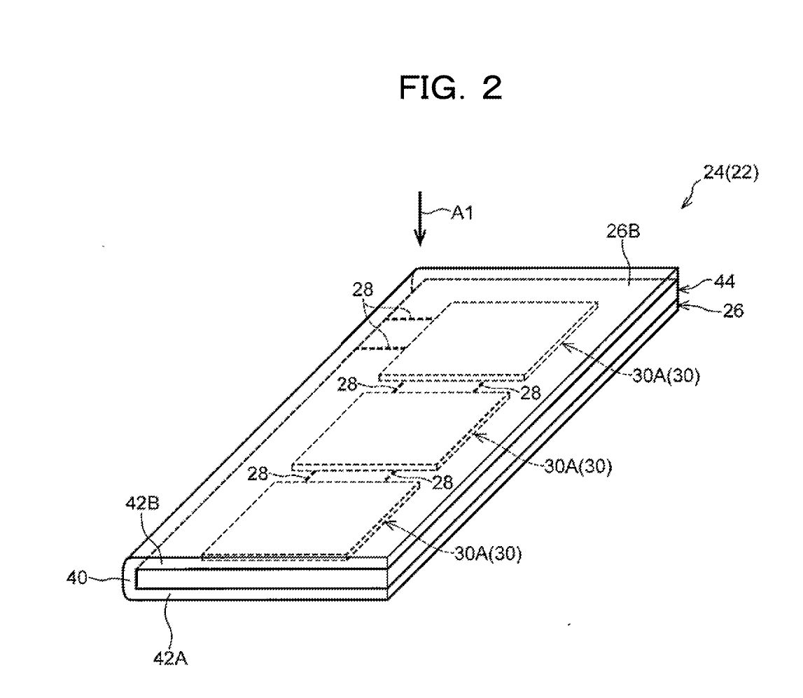

The electronic device 24 according to this embodiment has a configuration as illustrated in FIG. 2 and FIG. 3, in which the base member 26 of the substrate 22 is folded at the fold portion 40 and the covering member 44 is interposed between the upper and lower portions of the base member 26. For example, the electronic device 24 is disposed at a predetermined position under the ground or in a building and used as a device that transmits position information. The position at which the device is to be disposed may be curved or uneven. The electronic device 24 may be used without the base member 26 of the substrate 22 being folded in the manner as illustrated above (the configuration illustrated in FIG. 1). Alternatively, the electronic device 24 may be used in a form of folded at a predetermined position or in a rolled form.

Now, operations of this embodiment are described.

As illustrated in FIG. 2 and FIG. 3, the electricity storage unit 30B, the controlling unit 30C, and the communication unit 30D, which are mounted on the base member 26 of the electronic device 24, are covered with the covering member 44. The base member 26 is then folded at the fold portion 40 so as to hold the covering member 44 inside. By folding the base member 26 in this manner, various types of electronic components 30 are disposed so as to be superposed one on top of another in a plan view (viewed in a direction of arrow A1). Specifically, various types of electronic components are highly compactly arranged in a small space (within a range formed by folding the base member 26 in half). Since the covering member 44 is interposed between the superposed electronic components 30, the electronic components 30 are less likely to come into contact with one another.

As described above, the electronic device 24 is disposed at a predetermined position under the ground or in a building. When the position at which the electronic device 24 is disposed is flat, the base member 26 of the electronic device 24 remains flat, as illustrated in FIG. 5. Since the base member 26 is not curved, a stress does not occur at the junction portions 36. Even when the base member 26 is slightly curved, the stress that occurs at the junction portions 36 is kept low.

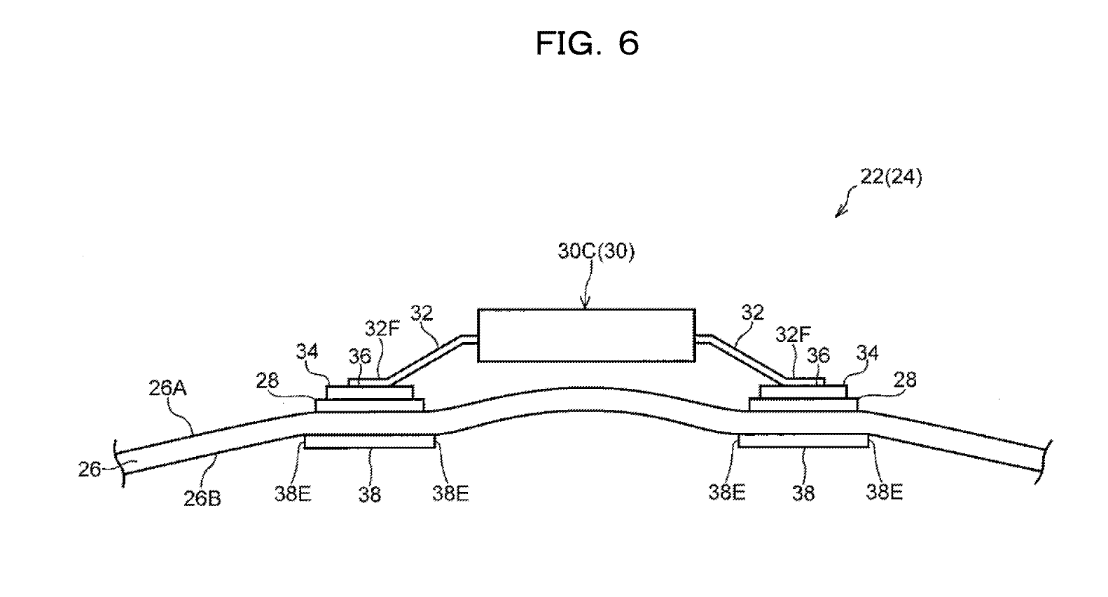

In the case, for example, where the position at which the electronic device 24 is disposed is curved, the electronic device 24 is bent in accordance with the shape of the portion at which the electronic device 24 is disposed. In this embodiment, the base member 26 and the conduction pattern 28 have flexibility. Thus, the electronic device 24 is allowed to be bent (see FIG. 6), expand, or contract (see arrow T1 in FIG. 5) in accordance with the shape of the portion at which the electronic device 24 is disposed.

In this embodiment, as illustrated in FIG. 6, the reinforcing members 38 are disposed on the reinforcement surface 26B of the base member 26 at positions opposite to the conduction patterns 28. Here, the configuration that does not include these reinforcing members 38 is assumed as a first comparative example. Here, the base member 26 and the conduction pattern 28 are bent since they have flexibility as described above, but the terminals 32 are less likely to be deformed since they are made of metal and have higher rigidity than the base member 26 and the conduction patterns 28. Thus, in the configuration according to the first comparative example that does not include the reinforcing members, a stress is more likely to concentrate at portions between the conduction patterns 28, which are bent, and the terminals 32, which remain flat, that is, at the junction portions 36.

In contrast, in this embodiment, the reinforcing members 38 are disposed at positions opposite to the conduction patterns 28. This configuration lessens the likelihood of deformation of the base member 26 and the conduction patterns 28 at portions at which the reinforcing members 38 are disposed. In other words, a stress concentrates on the base member 26 and the conduction patterns 28 near edge portions 38E of the reinforcing members 38 while the base member 26 and the conduction patterns 28 are deformed, so that stress concentration on the junction portions 36 are lessened. Thus, the likelihood of detachment of the terminals 32 from the conduction patterns 28 or damages to the terminals 32 from the conduction patterns 28 at the junction portions 36 is lessened.

Since deformation of the base member 26 and the conduction patterns 28 is not restricted in an area in which the reinforcing members 38 are not disposed, the base member 26 and the conduction patterns 28 are allowed to be deformed into a smoothly bent shape in such an area.

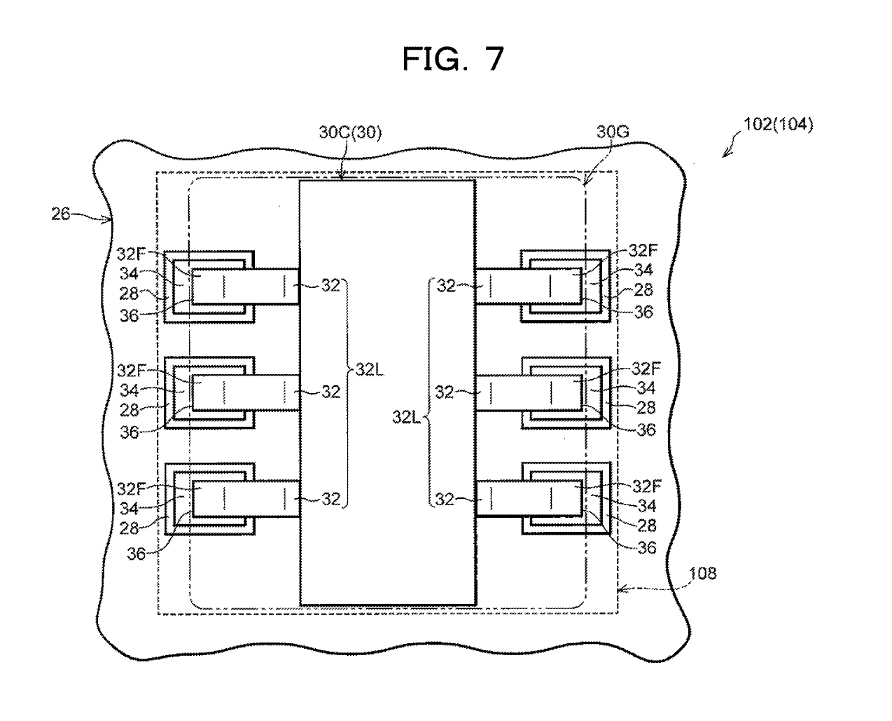

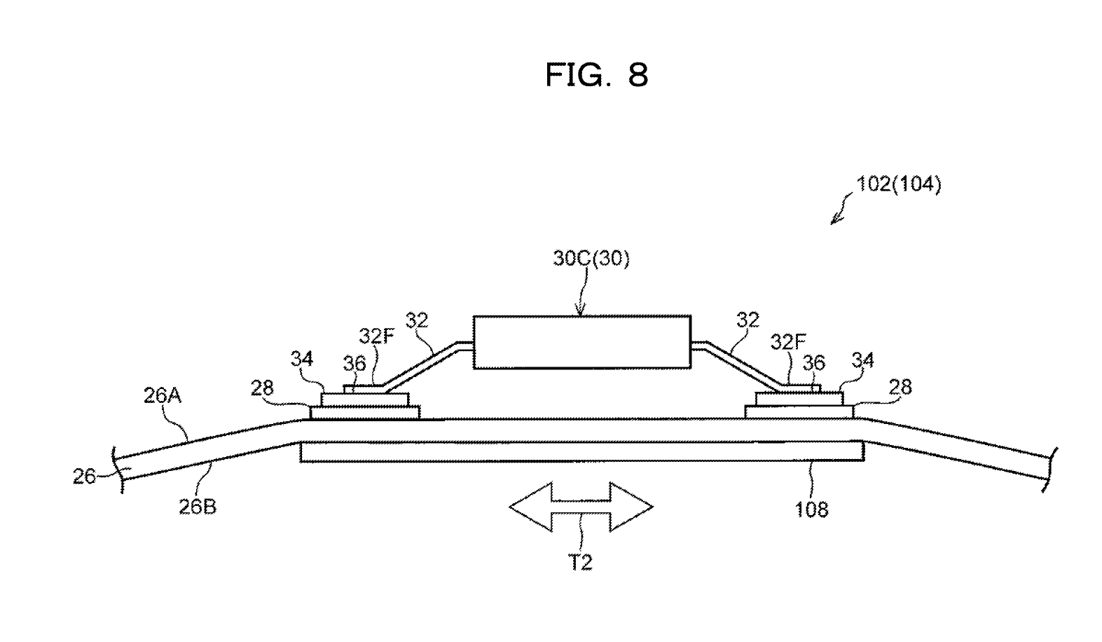

When the base member 26 is viewed in a plan, the reinforcing members 38 are smaller than the controlling unit 30C (example of an electronic component). Here, as a second comparative example, FIG. 7 and FIG. 8 illustrate part of a base member 102 (electronic device 104) in which a reinforcing member 108, which is larger than the entire area 30G of the controlling unit 30C (see FIG. 4), is disposed on the reinforcement surface 26B of the base member 26.

In the configuration of the second comparative example, the reinforcing member 108 enables lessening of the stress concentration on the junction portions 36. However, the base member 26 is less likely to be deformed (be bent, expand, or contract) as a whole than in the case of the electronic device 24 according to the first embodiment since the reinforcing member 108 is larger than the controlling unit 30C. As indicated with arrow T2 in FIG. 8, the base member 26 is allowed to expand or contract to a lesser extent. In contrast, in the electronic component 30 according to the first embodiment, the reinforcing members 38 are smaller than the controlling unit 30C and thus the base member 26 is easily deformed (with a small amount of force).

Moreover, this embodiment achieves a configuration in which the base member 26 and the conduction patterns 28 are easily deformed without forming slits, thin portions, or the like in the reinforcing members 38. Since the reinforcing members 38 have neither slits nor thin portions, manufacturing of the substrate 22 is easy and the strength of the reinforcing members 38 is not locally lowered.

As long as the likelihood of damages at the junction portions 36 is lessened at the time of deformation while the base member 26 is allowed to be easily deformed in the manner as describe above, a configuration according to the following second embodiment or third embodiment may be adopted. In the second embodiment or the third embodiment, components or the like that are the same as those in the case of the first embodiment are denoted with the same reference symbols and are not described in detail.

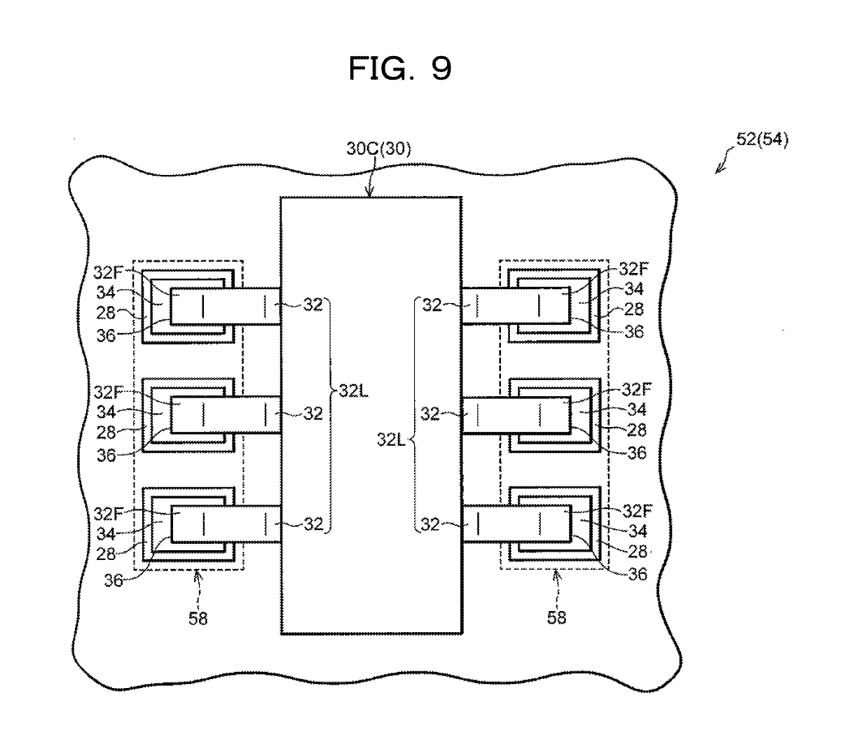

On a substrate 52 (electronic device 54) according to the second embodiment, part of which is illustrated in FIG. 9, a reinforcing member 58 is provided for each terminal row 32L. In other words, a common reinforcing member 58 is provided for three conduction patterns 28 corresponding to multiple terminals 32 (three terminals in FIG. 9) in each terminal row 32L.

Also in the configuration according to the second embodiment, the reinforcing members 58 are disposed on the side opposite to the conduction patterns 28. Thus, when the base member 26 is bent, stress concentration on the junction portions 36 is lessened and the likelihood of detachment of the terminals 32 from the conduction patterns 28 or damages to the terminals 32 from the conduction patterns 28 at the junction portions 36 is lessened.

Also in the second embodiment, the reinforcing members 58 are smaller than the controlling unit 30C. Thus, the base member 26 is more easily deformed (with a smaller amount of force) than in the case of the configuration according to the second comparative example (see FIG. 7 and FIG. 8).

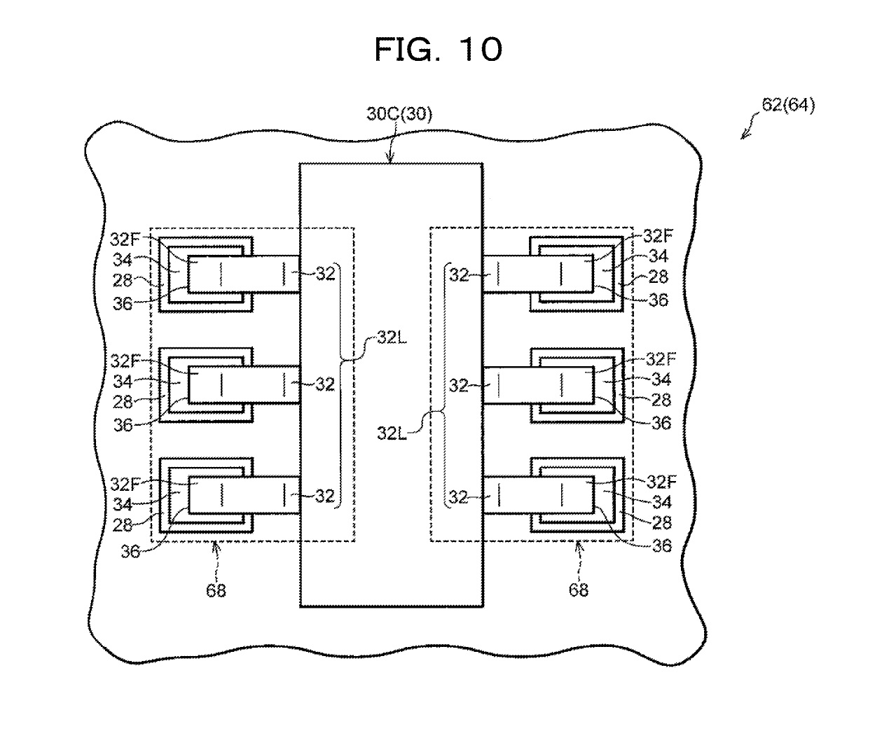

A substrate 62 (electronic device 64) according to a third embodiment, part of which is illustrated in FIG. 10, includes a reinforcing member 68 for each terminal row 32L, as in the case of the reinforcing member 58 according to the second embodiment. The controlling unit 30C of the reinforcing member 68 according to the third embodiment, however, has a larger width than the reinforcing member 58 according to the second embodiment so as to expand toward the middle of the controlling unit 30C in the widthwise direction.

Also in the configuration according to the third embodiment, the reinforcing members 68 are disposed on the side opposite to the conduction patterns 28. Thus, when the base member 26 is bent, stress concentration on the junction portions 36 is lessened and the likelihood of detachment of the terminals 32 from the conduction patterns 28 or damages to the terminals 32 from the conduction patterns 28 at the junction portions 36 is lessened.

Also in the third embodiment, the reinforcing members 68 are smaller than the controlling unit 30C. Thus, the base member 26 is more easily deformed (with a smaller amount of force) than in the case of the configuration of the second comparative example (see FIG. 7 and FIG. 8).

In this manner, when the reinforcing member is smaller than the controlling unit 30C when the base member 26 is viewed in a plan, the base member 26 is allowed to be deformed more easily than in the case of the configuration in which the reinforcing member is larger than the base member 26. In addition, when the reinforcing member is larger than each junction portion 36 of the terminal 32, a stress that occurs in the junction portion 36 is highly effectively lessened since the entirety of the junction portion 36 lessens the likelihood of deformation of the conduction pattern 28.

In the first embodiment, the reinforcing members 38 are provided to the respective conduction patterns 28 (terminals 32) so that the conduction patterns 28 (terminals 32) correspond one-to-one to the reinforcing members 38. Since the reinforcing members 38 are separately provided for the conduction patterns 28, this configuration is regarded as being advantageous in that it allows easy deformation of the base member 26.

In the second embodiment and the third embodiment, on the other hand, the reinforcing member 68 is larger than the reinforcing member according to the first embodiment. Such a configuration, in which a portion at which a stress concentrates during deformation of the base member 26 is spaced further apart from the junction portions 36, is advantageous in that it more securely lessens the likelihood of damages at the junction portions 36.

In the second embodiment and the third embodiment, three (or may be more) conduction patterns 28 share the same reinforcing member 58 or 68. In other words, in the second embodiment and the third embodiment, the number of reinforcing members is smaller than in the case of the first embodiment. These configurations thus facilitate disposition of the reinforcing members 58 or 68 on the base member 26.

Particularly, in the second embodiment and the third embodiment, one common reinforcing member 58 or 68 is provided for multiple conduction patterns 28 of each terminal row 32L. Thus, the shape of the reinforcing members 58 or 68 may be simplified, whereby the reinforcing members 58 or 68 are easily formed.

Now, the method for forming the reinforcing members 38, 58, or 68 on the base member 26 is not limited to a particular method. For example, a sheet-shaped reinforcing member (reinforcement sheet) that covers substantially the entirety of the reinforcement surface 26B may be prepared and bonded to the reinforcement surface 26B and then the excess portion may be removed. This method is easily performed since it does not involve highly accurate positioning when the reinforcement sheet is bonded to the reinforcement surface 26B. Particularly, fewer components (or no components) are mounted on the reinforcement surface 26B than on the component onboard surface 26A. Thus, the reinforcement surface 26B is less uneven and allows the reinforcing members 38, 58, or 68 to be easily disposed thereon. Moreover, the reinforcing members 38, 58, or 68 are not embedded in the base member 26. Also in this regard, disposition of the reinforcing members 38, 58, or 68 is facilitated.

Now, a fourth embodiment is described. In the fourth embodiment, components or the like that are the same as those of the first embodiment are denoted with the same reference symbols and not described in detail.

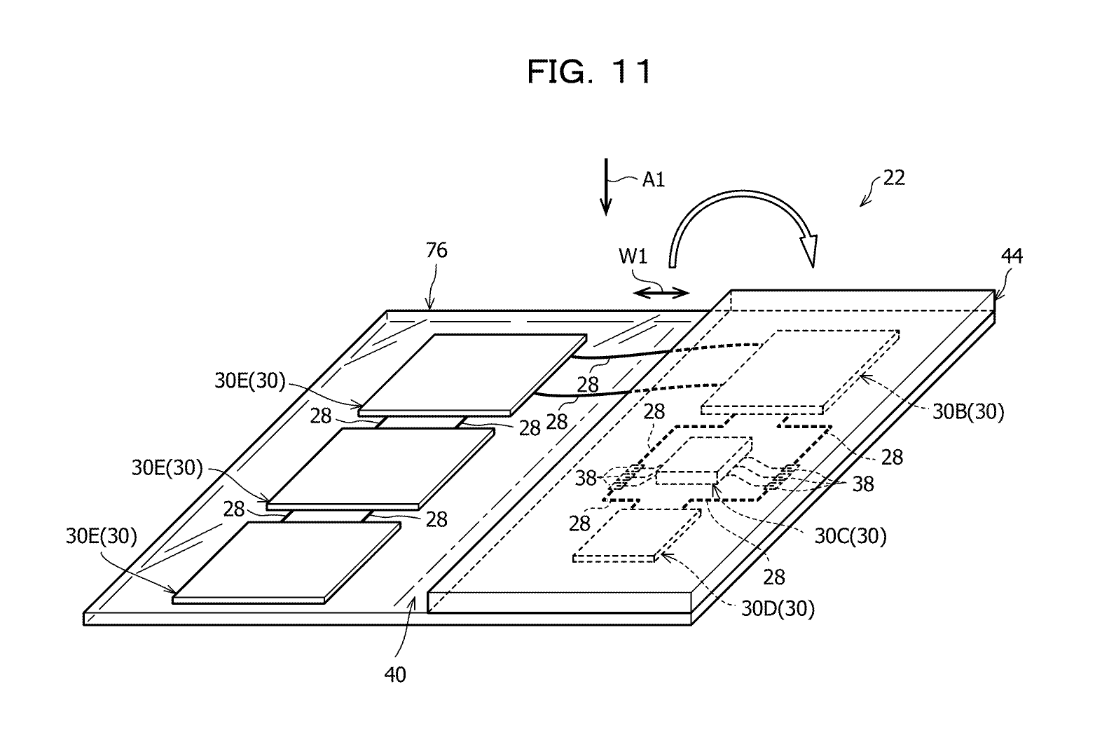

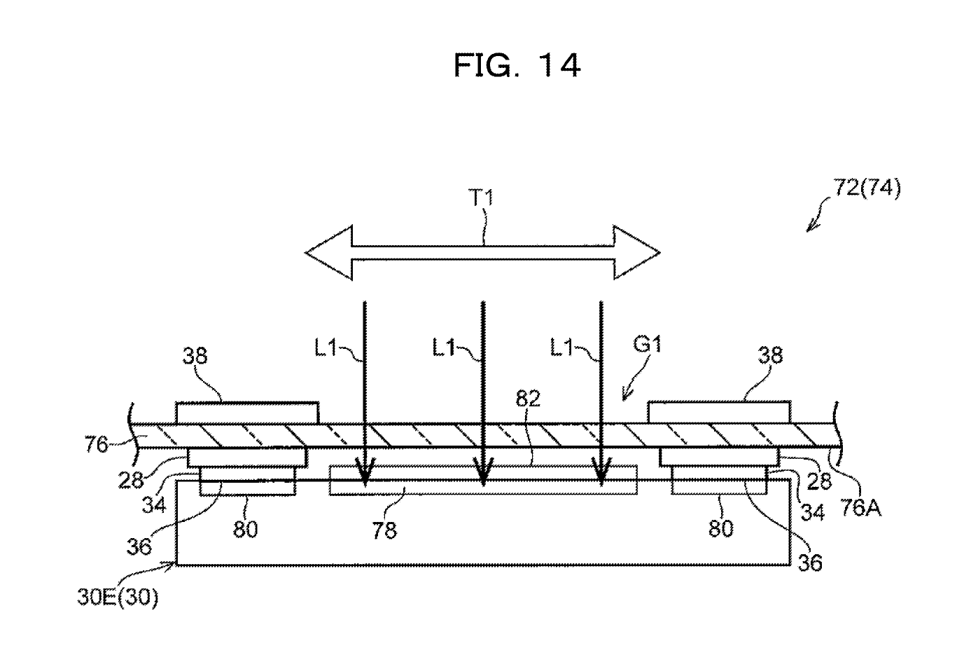

As illustrated in FIG. 11 to FIG. 13, instead of the power supply units 30A of the electronic device 24 according to the first embodiment, solar cells 30E are disposed on a substrate 72 (electronic device 74) according to the fourth embodiment. As illustrated in FIG. 14, each solar cell 30E is disposed so that its light receiving portion 78 is directed toward a base member 76. The light receiving portion 78 is protected by a light transmissive cover 82.

Each solar cell 30E includes electrodes 80. Each electrode 80 is bonded to the corresponding conduction pattern 28 formed on a component onboard surface 76A of the base member 76 with a bonding agent 34. The reinforcing members 38 are disposed on the reinforcement surface 26B of the base member 76. Each reinforcing member 38 is smaller than the corresponding solar cell 30E and larger than the corresponding junction portion 36. Each solar cell 30E may supply power to the external devices through the electrodes 80.

The solar cells 30E according to the fourth embodiment are examples of electronic components and the electrodes 80 of each solar cell 30E are examples of the terminals.

The base member 76 according to the fourth embodiment is transparent. The wording “the base member 76 is transparent” here means that the base member 76 allows light to pass therethrough to such a degree that each solar cell 30E is capable of generating power in response to an incidence of the light on the light receiving portion 78 of the solar cell 30E.

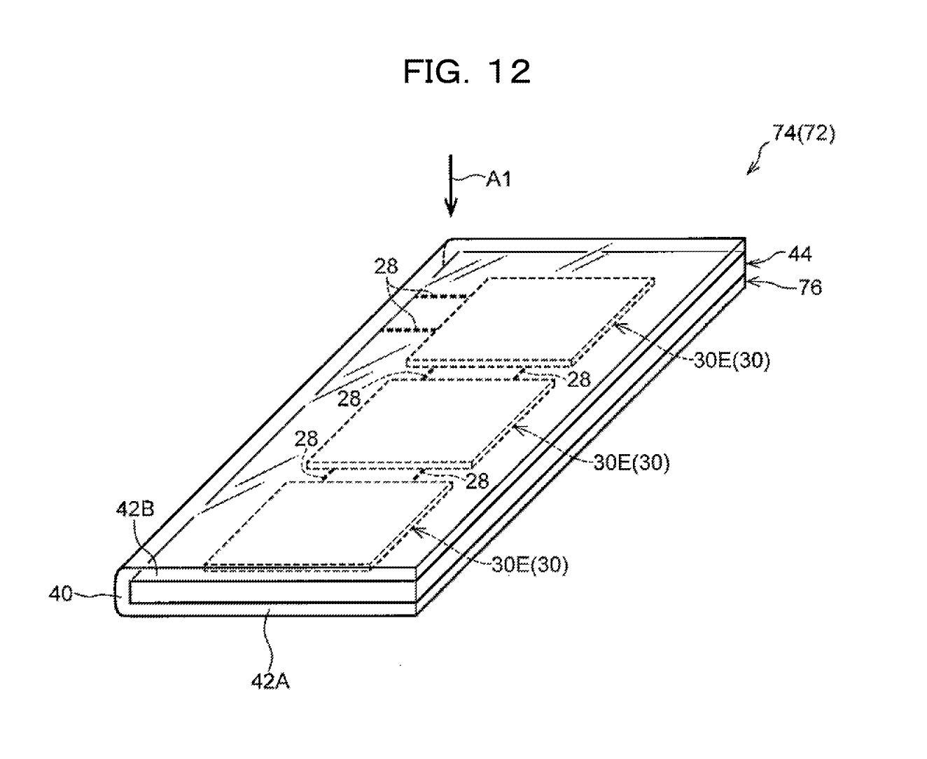

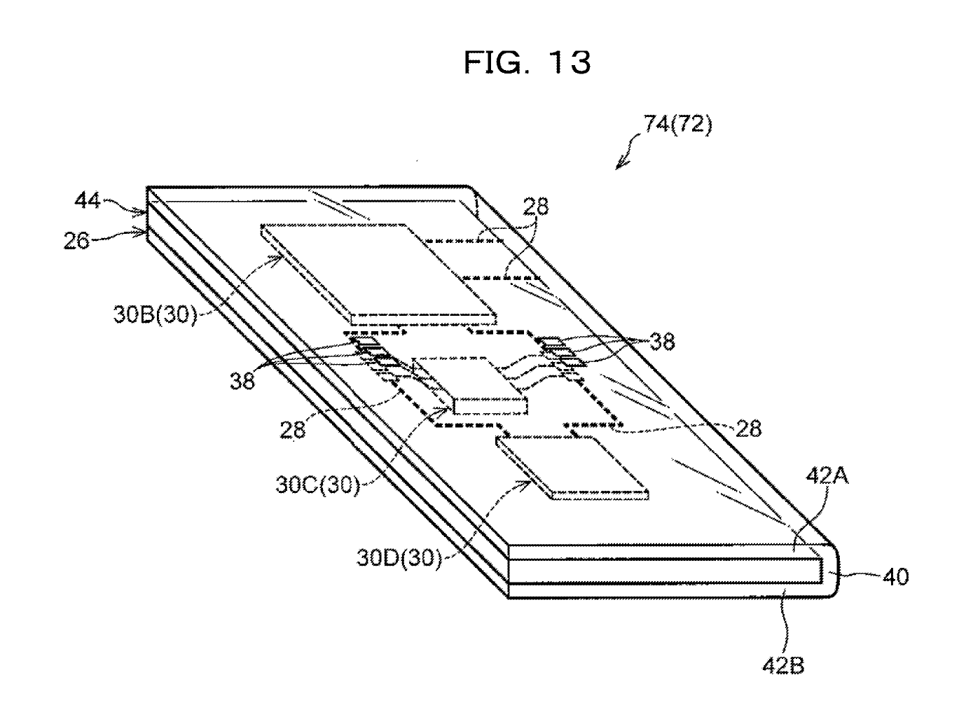

As illustrated in FIG. 12 and FIG. 13, the electronic device 74 has a configuration in which the base member 76 is folded at the fold portion 40 so as to hold the covering member 44 inside. The light receiving portion 78 of each solar cell 30E is thus directed to the outer side of the electronic device 74 (upward in FIG. 14).

Also in the electronic device 74 according to the fourth embodiment, the reinforcing members 38 are disposed on the side opposite to the conduction patterns 28. Thus, when the base member 26 is bent, stress concentration on the junction portions 36 is lessened and the likelihood of detachment of the terminals from the conduction patterns 28 or damages to the terminals from the conduction patterns 28 at the junction portions 36 is lessened. In addition, since the reinforcing members 38 are smaller than the controlling unit 30C, the base member 26 is easily deformed (with a smaller amount of force) than in the case of the configuration according to the second comparative example.

In the fourth embodiment, the base member 76 is transparent. Thus, external light is allowed to be reliably incident on the light receiving portion 78 of each solar cell 30E as indicated with arrow L1 in FIG. 14, so that the solar cell 30E may generate power.

The solar cell 30E is disposed in such a manner that the light receiving portion 78 is directed toward the base member 76. In the electronic device 24, each light receiving portion 78 faces outward. Thus, external light is reliably applied to the light receiving portion 78.

Each reinforcing member 38 is smaller than the corresponding solar cell 30E. More specifically, a gap G1 is left between multiple (two) reinforcing members 38 illustrated in FIG. 14. In other words, two reinforcing members 58 are disposed at such positions as not to overlap the light receiving portion 78 (gap G1).

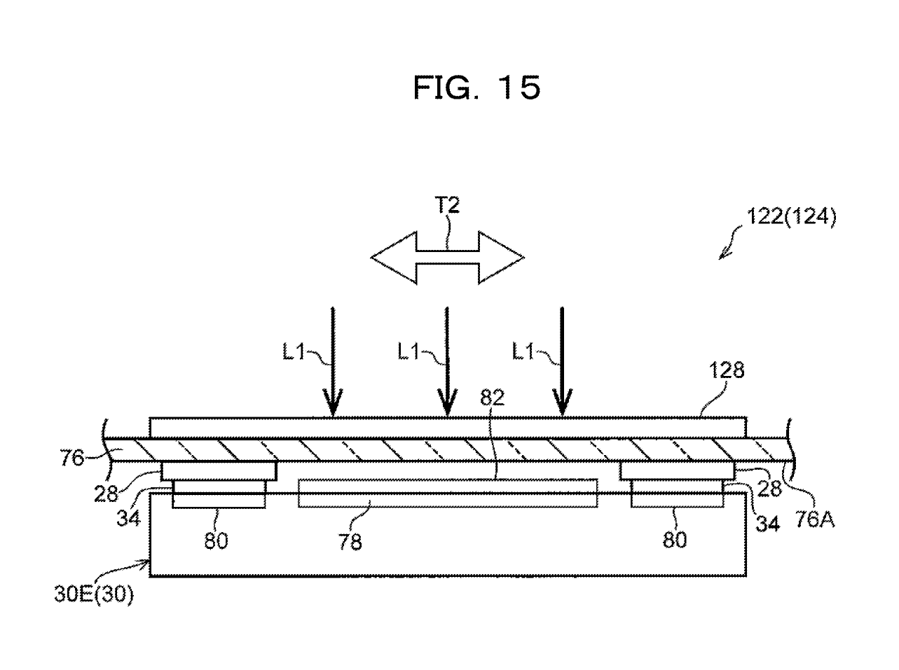

FIG. 15 illustrates part of a substrate 122 (electronic device 124) according to a third comparative example. In the third comparative example, a reinforcing member 128 is larger than the corresponding solar cell 30E. In the configuration of the third comparative example, the reinforcing member 128 covers the light receiving portion 78, so that external light fails to reach the light receiving portion 78. In the fourth embodiment, on the other hand, external light is allowed to be applied to the light receiving portion 78 through the gap G1 between two reinforcing members 38.

In each embodiment, the modulus of longitudinal elasticity of the reinforcing members 38, 58, or 68 is higher than the modulus of longitudinal elasticity of the base member 26 and the modulus of longitudinal elasticity of the conduction patterns 28. Thus, the configuration in which the reinforcing members 38, 58, or 68 are less likely to be deformed by an external force than in the case of the base member 26 and the conduction patterns 28 is easily achieved.

Even when the modulus of longitudinal elasticity of the reinforcing members is equivalent to or lower than the modulus of longitudinal elasticity of the base member 26 or the modulus of longitudinal elasticity of the conduction patterns 28, the configuration in which the reinforcing members are less likely to be deformed by an external force than in the case of the base member 26 and the conduction patterns 28 is achieved by, for example, increasing the thickness of the reinforcing members. Increasing the thickness of the reinforcing members, however, causes the reinforcing members to protrude from the base member 26. Thus, an electronic device having this configuration may be difficult to install depending on the location. Thus, in each embodiment, the modulus of longitudinal elasticity of the reinforcing members 38, 58, or 68 is determined to be higher than the modulus of longitudinal elasticity of the base member 26 and the modulus of longitudinal elasticity of the conduction patterns 28, so as to achieve a configuration in which the reinforcing members 38, 58, or 68, which are thin, are less likely to be deformed by an external force. Rendering the reinforcing members 38, 58, or 68 thin allows the electronic device 24, 54, 64, or 74 to be easily installed.

A configuration in which each terminal 32 is joined to the corresponding conduction pattern 28 is not limited to a particular configuration. However, using the bonding agent 34 as in each of the above-described embodiments allows the terminals 32 to be joined to the respective conduction patterns 28 with a simple configuration.

Using a bonding agent having electrical conductivity as the bonding agent 34 allows the terminals 32 and the conduction patterns 28 to be electrically connected together even with the bonding agent interposed between the terminals 32 and the respective conduction patterns 28.

Examples of the electronic device are not limited to the devices installed at predetermined positions under the ground or in a building as described above. For example, the electronic device may be part of an ornament or equipment attached to clothes or worn by persons. More specifically, examples of the electronic device include a device that detects the position, movement, or circumstances of a wearer and transmits input information to other electronic devices or the like. Such an electronic device may achieve an integrated configuration as a whole by allowing an electronic component functioning as a sensor and an electronic component that transmits and receives electronic waves to be mounted on a single base member.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A substrate comprising:
a base member that has flexibility and insulation properties;
an electrically conductive member that is disposed on a top surface of the base member and that has flexibility and electrical conductivity;
an electronic component that is disposed over the base member and that includes a terminal joined to the electrically conductive member; and
a reinforcing member that is disposed on a bottom surface of the base member at a portion corresponding to a portion of the top surface of the base member at which the electrically conductive member is disposed,
wherein the reinforcing member is larger in size than an area over which the terminal and the electrically conductive member are joined together.

2. The substrate according to claim 1,
wherein the reinforcing member is smaller than an area over which the electronic component, which includes the terminal, is mounted.

3. The substrate according to claim 1,
wherein the electronic component includes a plurality of the terminals,
wherein a plurality of the electrically conductive members are disposed so as to correspond to the plurality of terminals, and
wherein a plurality of the reinforcing members are disposed so as to correspond to the plurality of electrically conductive members.

4. The substrate according to claim 1,
wherein the electronic component includes three or more of the terminals,
wherein a plurality of the electrically conductive members are disposed so as to correspond to the three or more terminals, and
wherein the reinforcing member is used in common between the plurality of electrically conductive members.

5. The substrate according to claim 1,
wherein the electronic component includes a plurality of terminal rows in each of which a plurality of the terminals are arranged, and
wherein the reinforcing member is used in common between the plurality of terminals in each terminal row.

6. The substrate according to claim 1,
wherein the reinforcing member has a modulus of longitudinal elasticity that is higher than a modulus of longitudinal elasticity of the base member.

7. The substrate according to claim 1,
wherein the reinforcing member has a modulus of longitudinal elasticity that is higher than a modulus of longitudinal elasticity of the electrically conductive member.

8. The substrate according to claim 1,
wherein the base member is made of a material that transmits light.

9. The substrate according to claim 8,
wherein the electronic component is a solar cell that includes a light receiving portion and that is disposed so that the light receiving portion faces the base member.

10. The substrate according to claim 9,
wherein the reinforcing member is disposed over the base member at a portion of the solar cell that does not overlap the light receiving portion.

11. The substrate according to claim 1,
wherein the terminal is bonded to the electrically conductive member using a bonding agent.

12. The substrate according to claim 11,
wherein the bonding agent has electrical conductivity.

13. An electronic device comprising:
a substrate, the substrate includes
a base member that has flexibility and insulation properties,
an electrically conductive member that is disposed on a top surface of the base member and that has flexibility and electrical conductivity,
an electronic component that is disposed over the base member and that includes a terminal joined to the electrically conductive member, and
a reinforcing member that is disposed on a bottom surface of the base member at a portion corresponding to a portion of the top surface of the base member at which the electrically conductive member is disposed, and
wherein the reinforcing member is larger in size than an area over which the terminal and the electrically conductive member are joined together.

14. The electronic device according to claim 13, further comprising:
a covering member that covers the electronic component so that the electronic component is interposed between the covering member and the base member,
wherein the base member is folded so as to hold the covering member inside.
